(19) United States
(12) Patent Application Publication
(10) Pub. No.: US 2025/0031473 A1
(43) Pub. Date: Jan. 23, 2025

(54) IMAGE SENSOR AND MANUFACTURING METHOD OF IMAGE SENSOR

(71) Applicant: SAMSUNG ELECTRONICS CO., LTD., Suwon-si (KR)

(72) Inventors: Hyungchae KIM, Suwon-si (KR); Jinhwa HAN, Suwon-si (KR); Jinsuk HUH, Suwon-si (KR)

(73) Assignee: SAMSUNG ELECTRONICS CO., LTD., Suwon-si (KR)

(21) Appl. No.: 18/667,657

(22) Filed: May 17, 2024

(30) Foreign Application Priority Data
Jul. 19, 2023 (KR) 10-2023-0093861

(51) Int. Cl. H01L 27/146

(52) U.S. Cl. CPC H01L 27/1463; H01L 27/14612; H01L 27/14643

(57) ABSTRACT

An image sensor includes: a substrate having a first surface and a second surface opposite to the first surface in a first direction, the substrate including pixel areas arranged along a second direction parallel to the first surface; photodiodes in the substrate in each of the pixel areas and separated from each other in the second direction; a first device isolation layer between the pixel areas; and a pair of second device isolation layers extending between the photodiodes from the first device isolation layer along a third direction and being spaced apart from each other in the third direction, wherein the third direction is parallel to the first surface and different from the second direction, the substrate further includes a potential barrier region between the photodiodes and between the pair of second device isolation layers, and the potential barrier region includes p-type impurities and carbon.

### CROSS-REFERENCE TO RELATED APPLICATION

This application claims priority to Korean Patent Application No. 10-2023-0093861, filed on Jul. 19, 2023, in the Korean Intellectual Property Office, the disclosure of which is incorporated by reference herein in its entirety.

### BACKGROUND

### 1. Field

This disclosure relates to an image sensor and a manufacturing method of the image sensor.

### 2. Description of Related Art

An image sensor is a semiconductor device that converts optical images into electrical signals. Among them, a complementary metal-oxide-semiconductor (CMOS) image sensor (CIS) includes a plurality of pixel areas, and each pixel area includes at least one photodiode (PD) that converts incident light into an electrical signal. The CIS, which has a structure including two photodiodes in one pixel area, can have improved autofocus performance.

### SUMMARY

Embodiments of the present disclosure provide an image sensor which may be capable of improving crosstalk between photodiodes, suppressing optical loss, and improving dark current characteristics, and a method of manufacturing the same.

According to an aspect of an embodiment, an image sensor includes: a substrate having a first surface and a second surface opposite to the first surface in a first direction, the substrate including pixel areas arranged along a second direction parallel to the first surface; photodiodes in the substrate in each of the pixel areas and separated from each other in the second direction; a first device isolation layer between the pixel areas; and a pair of second device isolation layers extending between the photodiodes from the first device isolation layer along a third direction and being spaced apart from each other in the third direction, wherein the third direction is parallel to the first surface and different from the second direction, the substrate further includes a potential barrier region between the photodiodes and between the pair of second device isolation layers, and the potential barrier region includes p-type impurities and carbon.

According to an aspect of an embodiment, an image sensor includes: a substrate having a first surface and a second surface opposite to the first surface in a first direction, the substrate including pixel areas arranged along a second direction parallel to the first surface; photodiodes in the substrate in each of the pixel areas and separated from each other in the second direction; a first device isolation layer between the pixel areas; and a pair of second device isolation layers extending between the photodiodes from the first device isolation layer along a third direction and being spaced apart from each other in the third direction, wherein the third direction is parallel to the first surface and different from the second direction; wherein the substrate further includes a first doped region adjacent to a sidewall of the second device isolation layers, and the first doped region includes p-type impurities and carbon, in a first region of the first doped region where a distance from a surface adjacent to the second device isolation layers in a vertical direction is less than or equal to about 50 nm, a concentration of the p-type impurities is greater than a concentration of the carbon, and in a second region of the first doped region where a distance from surface adjacent to the second device isolation layers in the vertical direction is greater than about 50 nm, a concentration of the carbon is greater than a concentration of the p-type impurities.

According to an aspect of an embodiment, an image sensor includes: a substrate having a first surface and a second surface opposite to the first surface in a first direction, the substrate including pixel areas arranged along a second direction parallel to the first surface; photodiodes in the substrate in each of the pixel areas and separated from each other in the second direction and a third direction parallel to the first surface and different from the second direction; a first device isolation layer between the pixel areas; a pair of second device isolation layers extending between the photodiodes from the first device isolation layer along the third direction and spaced apart from each other in the third direction; and another pair of second device isolation layers extending from the first device isolation layer between the photodiodes along the second direction and spaced apart from each other in the second direction, wherein the substrate further includes a potential barrier region between the photodiodes and the second device isolation layers, a first doped region adjacent to a sidewall of the second device isolation layers, a second doped region adjacent to a sidewall of the first device isolation layer, and a third doped region on the first surface, and each of the potential barrier region, the first doped region, the second doped region, and the third doped region includes p-type impurities and carbon.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 is a block diagram of an image sensor according to an embodiment;

FIG. 2 is a top view of an image sensor according to an embodiment;

FIG. 3 is a cross-sectional view taken along line I-I′ of FIG. 2;

FIG. 4 is a cross-sectional view taken along line II-II′ of FIG. 2;

FIG. 5 is a cross-sectional view taken along line III-III′ of FIG. 2;

FIG. 6 is a top view of an image sensor according to another embodiment;

FIG. 7 is a cross-sectional view taken along line I-I′ of FIG. 6;

FIG. 8 is a cross-sectional view taken along line II-II′ of FIG. 6;

FIG. 9 is a cross-sectional view taken along line III-III′ of FIG. 6;

FIG. 10 is a top view of an image sensor according to another embodiment;

FIG. 11 is a cross-sectional view taken along line I-I′ of FIG. 10;

FIG. 12 is a cross-sectional view taken along line II-II′ of FIG. 10;

FIG. 13 is a cross-sectional view taken along line III-III′ of FIG. 10; and

FIGS. 14 to 24 are cross-sectional views showing intermediate steps in a method of manufacturing an image sensor according to an embodiment.

### DETAILED DESCRIPTION

Embodiments of the present disclosure will be described more fully hereinafter with reference to the accompanying drawings. As those skilled in the art will realize, the described embodiments may be modified in various different ways, all without departing from the spirit or scope of the present disclosure.

The drawings and description are to be regarded as illustrative in nature and not restrictive. Like reference numerals designate like elements throughout the specification.

The size and thickness of each constituent element as shown in the drawings are randomly indicated for better understanding and ease of description, and this disclosure is not necessarily limited to as shown. In the drawings, the thickness of layers, regions, etc., are exaggerated for clarity. In addition, in the drawings, for better understanding and ease of description, the thickness of some layers and areas is exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. The word “on” or “above” means being disposed on or below the object portion, and does not necessarily mean being disposed on the upper side of the object portion based on a gravitational direction.

In addition, unless explicitly described to the contrary, the words “comprise” and “include” and variations thereof will be understood to imply the inclusion of stated elements but not the exclusion of any other elements.

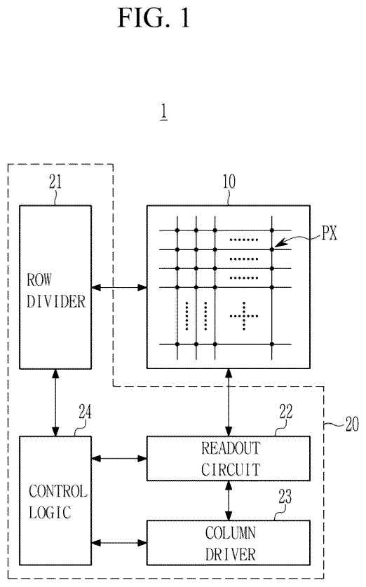

An image sensor 100 according to an embodiment will be described with reference to FIGS. 1 to 5.

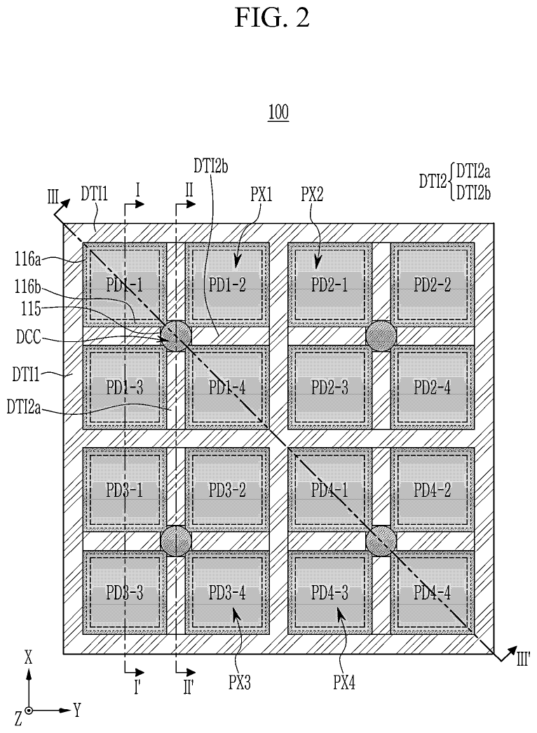

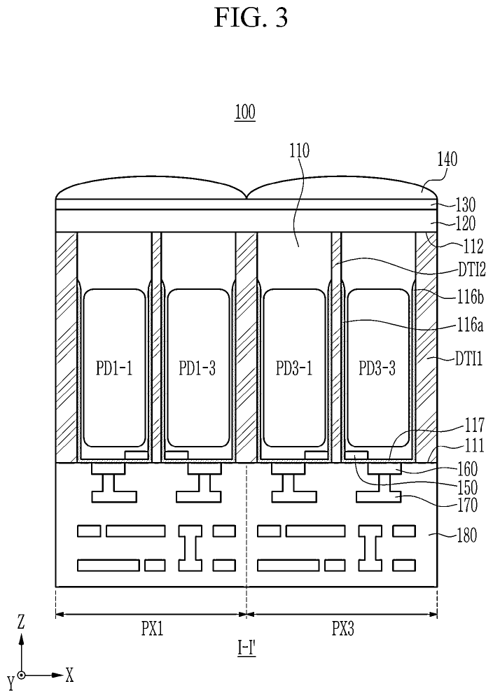

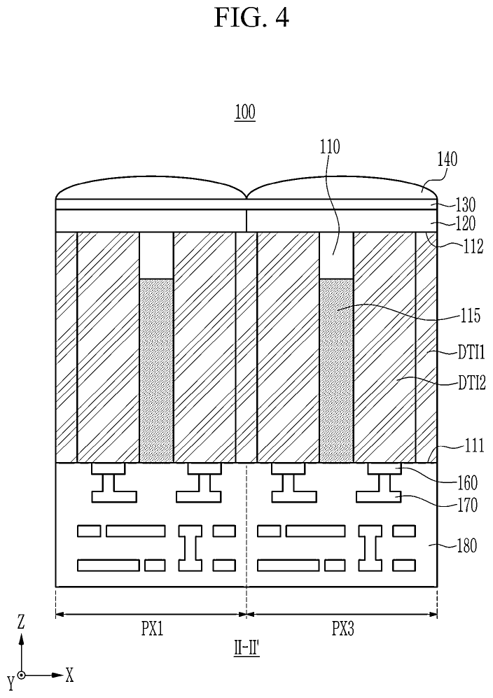

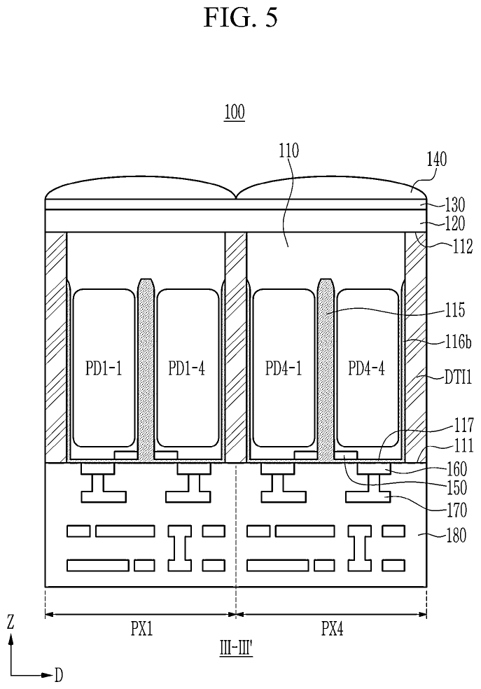

FIG. 1 is a block diagram of an image sensor according to an embodiment, FIG. 2 is a top view of an image sensor according to an embodiment, FIG. 3 is a cross-sectional view taken along line I-I′ of FIG. 2, FIG. 4 is a cross-sectional view taken along line II-II′ of FIG. 2, and FIG. 5 is a cross-sectional view taken along line III-III′ of FIG. 2.

Referring to FIG. 1, the image sensor 100 according to an embodiment may include a pixel array 10 and a logic circuit 20.

The pixel array 10 may include a plurality of unit pixels PXs arranged in an array along a plurality of rows and a plurality of columns. Each of the unit pixels PXs may include at least one photoelectric conversion element that generates charge in response to light, and a pixel circuit that generates a pixel signal corresponding to the charge generated by the photoelectric conversion element.

The photoelectric conversion element may include a photodiode formed of a semiconductor material, an organic material, and/or an organic-inorganic hybrid semiconductor material (e.g., organic-inorganic hybrid perovskite). In an embodiment, each of the unit pixels PXs may include two or more photoelectric conversion elements, and the two or more photoelectric conversion elements included in one unit pixel PX may receive light of different colors and generate charges.

In an embodiment, the unit pixels PXs may each include a plurality of photodiodes, and the photodiodes may each receive light of different wavelength bands and generate charges. For example, each unit pixel PX may include two or four photodiodes.

Depending on the embodiment, the pixel circuit may include a transfer transistor, a driving transistor, a selection transistor, and a reset transistor. When each of the unit pixels PXs has two or more photoelectric conversion elements, each of the unit pixels PXs may include a pixel circuit configured to process charges generated by each of the two or more photoelectric conversion elements. That is, when each of the unit pixels PXs has two or more photoelectric elements, the pixel circuit may include at least two of a transfer transistor, a driving transistor, a selection transistor, and a reset transistor.

The logic circuit 20 may include circuits configured to control the pixel

array 10. As an example, the logic circuit 20 may include a row driver 21, a readout circuit 22, a column driver 23, and control logic 24.

The row driver 21 may drive the pixel array 10 row by row. As an example, the row driver 21 generates a transmission control signal configured to control the transfer transistor of the pixel circuit, a reset control signal configured to control the reset transistor, a selection control signal configured to control the selection transistor, etc., which can be input to the pixel array 10 row by row.

The readout circuit 22 may include a correlated double sampler (CDS), an analog-to-digital converter (ADC), etc. The correlated double samplers may be connected via unit pixels PXs and column lines. The correlated double samplers can perform correlated double sampling by receiving pixel signals from unit pixels PXs connected to the row line selected by the row line selection signal of the row driver 21. Pixel signals can be received via column lines. The ADC may convert the pixel signal detected by the correlated double sampler into a digital pixel signal and transmit it to the column driver 23.

The column driver 23 may include a latch or buffer circuit capable of temporarily storing a digital pixel signal, an amplifier circuit, etc., and may process the digital pixel signal received from the readout circuit 22. The readout circuit 22 and the column driver 23 may be controlled by the control logic 24. The control logic 24 may include a timing controller configured to control operation timing of the row driver 21, the readout circuit 22, and the column driver 23.

Among the unit pixels PXs, unit pixels PXs disposed at the same position in the horizontal direction may share the same column line. For example, unit pixels PXs arranged at the same position in the vertical direction may be simultaneously selected by the row driver 21 and output pixel signals through column lines. In an embodiment, the readout circuit 22 may simultaneously obtain pixel signals from unit pixels PXs selected by the row driver 21 through column lines. The pixel signal may include a reset voltage and a pixel voltage, and the pixel voltage may be a voltage in which charges generated in response to light in each unit pixel PX are reflected in the reset voltage. However, the description made with reference to FIG. 1 may not be limited thereto, and the image sensor 100 may additionally include other components and may be driven in various ways.

Referring to FIG. 2, the image sensor 100, which includes photodiodes PD1-1 to PD4-4 arranged in four groups of four photodiodes PD1-1 to PD1-4, PD2-1 to PD2-4, PD3-1 to PD3-4, and PD4-1 to PD4-4 in pixel areas PX1, PX2, PX3, and PX4, respectively, may include a second device isolation layer DTI2 in order to improve sensitivity. In order for the image sensor 100 to operate smoothly without crosstalk (or signal disturbance), it is necessary to form a potential barrier region 115 of an appropriate height to control charges moving between the photodiodes PD1-1 to PD4-4 in the isolation layer-free region DCC.

However, the pixel structure of the image sensor 100 with the second device isolation layer DTI2 has a narrow isolation region between the photodiodes PD1-1 to PD4-4 and a large aspect ratio, and thus it is not easy to form a potential barrier region 115 that can effectively control the movement of charges between the photodiodes PD1-1 to PD4-4.

For example, by implanting p-type impurities using a plasma doping (PLAD) process, the side surfaces of the entire device isolation layer can be uniformly doped with impurities. Through this, a high-concentration p-type impurity region is formed in a narrow area between the photodiodes PD1-1 to PD4-4, thereby forming a high-performance image sensor 100 in which the photodiodes PD1-1 to PD4-4 are electrically separated.

However, in this method, it is difficult to selectively control the doping concentration at a specific location, it is difficult to form a high potential barrier due to the high diffusion characteristics of the p-type impurities, and there are limitations in forming completely electrically separated pixel areas PX1, PX2, PX3, and PX4.

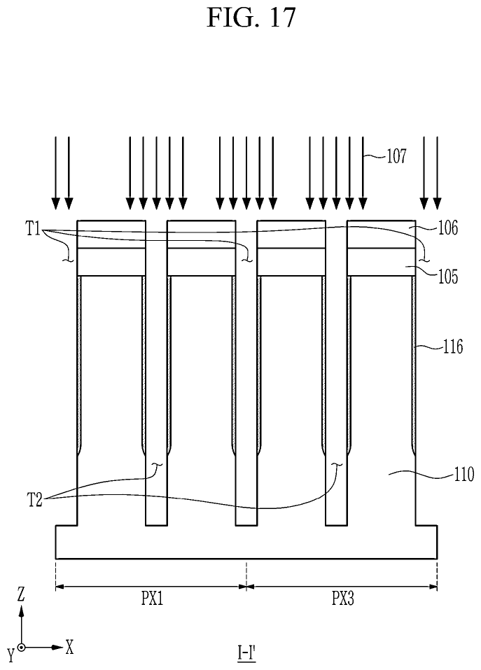

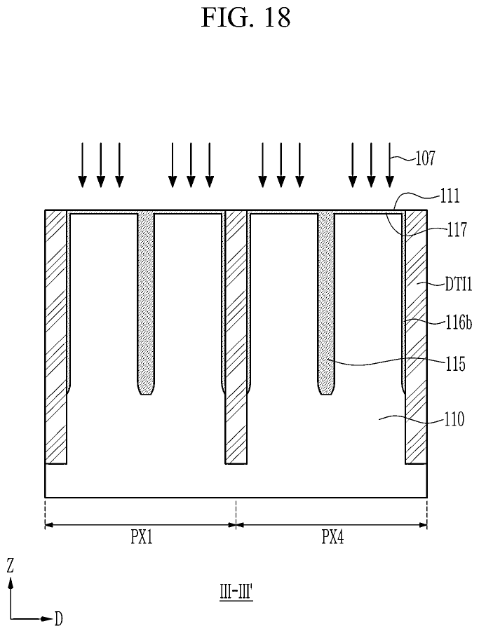

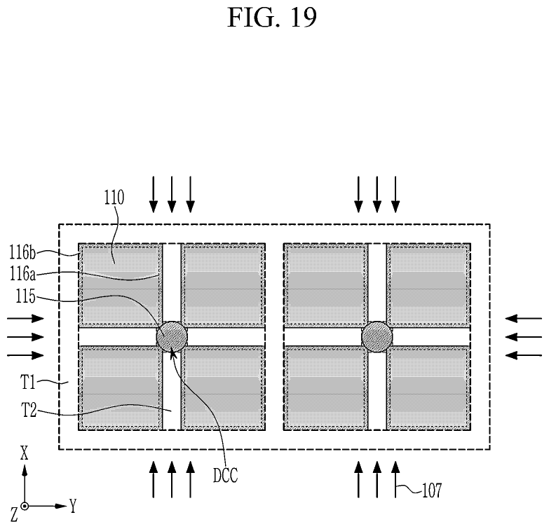

In order to solve the above problem, the image sensor 100 according to an embodiment performs carbon (C) implantation using an ion implantation process (IIP) in a region doped with p-type impurities, as will be described in FIGS. 17 to 19. By using the ion implantation process, diffusion of p-type impurities can be suppressed by controlling the carbon (C) doping concentration and depth at specific locations.

Without intending to be bound by a specific theory, the diffusion of p-type impurities, such as boron (B) and carbon (C), proceeds through silicon self-interstitials and substitution processes. In other words, the two dopants are in a competitive relationship in diffusion. Therefore, in a region rich in carbon (C), a rate at which carbon (C) consumes the self-interstitial of silicon is fast, slowing down the diffusion of boron (B).

Accordingly, the image sensor 100 according to an embodiment can suppress light loss and improve dark current characteristics by controlling the movement of charges between the photodiodes PD1-1 to PD4-4.

Continuing to refer to FIG. 2, the image sensor 100 according to an embodiment includes pixel areas PX1, PX2, PX3, and PX4, a first device isolation layer DTI1 disposed between the pixel areas PX1, PX2, PX3, and PX4, two pairs of second device isolation layers DTI2a and DTI2b respectively disposed inside the pixel areas PX1, PX2, PX3, and PX4, and first to fourth photodiodes PD1-1 to PD1-4, PD2-1 to PD2-4, PD3-1 to PD3-4, and PD4-1 to PD4-4 respectively disposed in the pixel areas PX1, PX2, PX3, and PX4 and separated by second device isolation layers DTI2a and DTI2b.

In the image sensor 100 according to an embodiment, the pixel areas PX1, PX2, PX3, and PX4 may be defined as including the substrate 110 and other circuits necessary for the operation of the image sensor 100. As an example, the substrate 110 may be a semiconductor substrate, and the substrate 110 may include first to fourth photodiodes PD1-1 to PD4-4 for receiving light.

The first device isolation layer DTI1 and the second device isolation layer DTI2 included in the image sensor 100 according to an embodiment may extend in a first direction (e.g., Z direction). As an example, the first device isolation layer DTI1 and the second device isolation layer DTI2 may include an insulating material.

The first device isolation layer DTI1 may separate the pixel areas PX1, PX2, PX3, and PX4 from each other and define each pixel area PX1, PX2, PX3, and PX4.

The second device isolation layer DTI2 may serve as a boundary separating the first to fourth photodiodes PD1-1 to PD1-4, PD2-1 to PD2-4, PD3-1 to PD3-4, and PD4-1 to PD4-4. For example, within the first pixel area PX1, the first and second photodiodes PD1-1 and PD1-2 may be separated from each other in the second direction (e.g., Y direction), and the third and fourth photodiodes PD1-1 and PD1-2 may be separated from each other in the second direction (e.g., Y direction). Additionally, within the first pixel area PX1, the first and third photodiodes PD1-1 and PD1-3 may be separated from each other in a third direction (e.g., X direction), and the second and fourth photodiodes PD1-2 and PD1-4 may be separated from each other in a third direction may be separated from each other in a third direction. Herein, the second direction (e.g., Y direction) may be any direction parallel to the first surface 111 of the substrate 110, and the third direction (e.g., X direction) may be any direction parallel to the first surface 111 of the substrate 110 and different from the second direction. For example, the first, second, and third directions may be perpendicular to each other.

A pair of second device isolation layers DTI2a may extend between the first photodiodes PD1-1, PD2-1, PD3-1, and PD4-1 and second photodiodes PD1-2, PD2-2, PD3-2, and PD4-2 and between the third photodiodes PD1-3, PD2-3, PD3-3, and PD4-3 and fourth photodiodes PD1-4, PD2-4, PD3-4, and PD4-4 along the third direction from the first device isolation layer DTI1. A pair of second device isolation layers DTI2a may be spaced apart from each other in a third direction at the central portion of each of the pixel areas PX1, PX2, PX3, and PX4.

In addition, another pair of second device isolation layers DTI2b may extend between the first photodiodes PD1-1, PD2-1, PD3-1, and PD4-1 and third photodiodes PD1-3, PD2-3, PD3-3, and PD4-3 and between the second photodiodes PD1-2, PD2-2, PD3-2, and PD4-2 and the fourth photodiodes PD1-4, PD2-4, PD3-4, and PD4-4 along the second direction from the first device isolation layer DTI1. Another pair of second device isolation layers DTI2b may be spaced apart from each other in the second direction at the central portion of each of the pixel areas PX1, PX2, PX3, and PX4.

The substrate 110 includes an isolation layer-free region DCC disposed between the photodiodes PD1-1 to PD4-4 and the second device isolation layers DTI2, and a potential barrier region 115 is disposed in the isolation layer-free region DCC. As shown in FIG. 4, the potential barrier region 115 is formed between the pair of second device isolation layers DTI2a spaced apart from each other in the third direction and another pair of second device isolation layers DTI2b spaced apart from each other in the second direction. Additionally, as shown in FIG. 5, the potential barrier region 115 may be disposed between the photodiodes PD1-1 to PD4-4. FIG. 5 is a cross-sectional view taken along the line III-III′ of FIG. 2, where the line III-III′ is a line parallel to the first surface 111 of the substrate 110 and extending in a fourth direction (diagonal) different from the second and third directions (e.g., D direction). The fourth direction (diagonal) may be a diagonal direction between the second and third directions, which is perpendicular to the first direction and not perpendicular to the second and third directions.

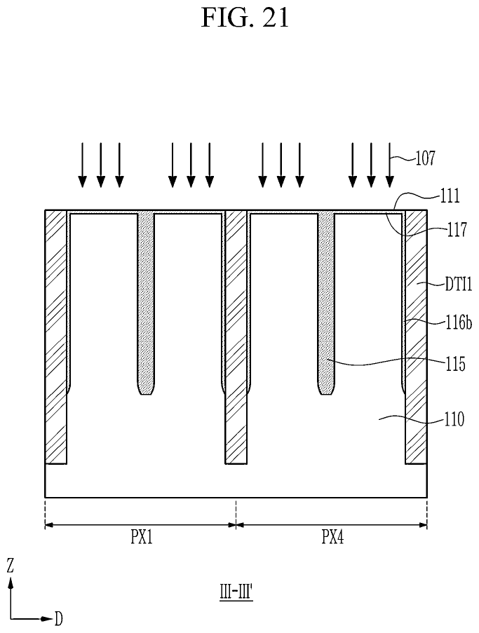

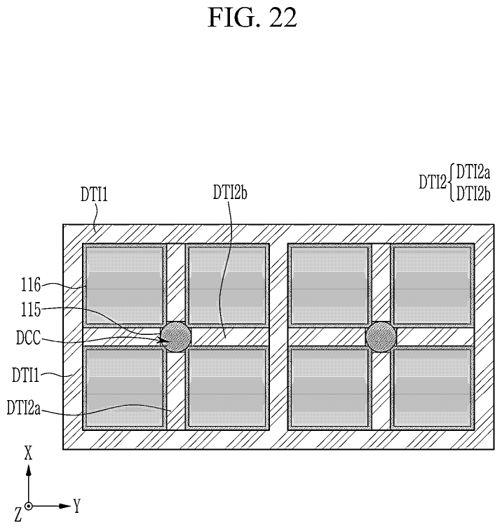

As explained in FIGS. 17 to 24 described later, the potential barrier region 115 may be formed before the first device isolation layer DTI1 and the second device isolation layer DTI2. As an example, the potential barrier region 115 may be an isolation layer-free region DCC inside the substrate 110 doped with impurities. As an example, the potential barrier region 115 may be separated from the first device isolation layer DTI1 in the second and third directions. Additionally, the potential barrier region 115 may be adjacent to the pair of second device isolation layers DTI2a in a third direction, and may be adjacent to another pair of second device isolation layers DTI2b in a second direction.

However, the shape of the potential barrier region 115 is not limited to what is shown in FIG. 2, and may vary depending on the shape of the second device isolation layer (DTI2) included in the image sensor 100 according to an embodiment, the manufacturing method of the image sensor 100, etc.

The potential barrier region 115 may include p-type impurities and carbon (C).

As an example, the p-type impurities may include boron (B), aluminum (Al), gallium (Ga), indium (In), or a combination thereof. For example, the p-type impurities may be boron (B).

In the entire bulk of the potential barrier region 115, the concentration of carbon (C) may be greater than the concentration of p-type impurities. For example, the concentration of carbon (C) may be about twice or more, about 5 times or more, about 10 times or more than the concentration of p-type impurities.

For example, in the entire potential barrier region 115, the concentration of carbon (C) may be about 1×10¹⁸ at/cm³ to about 1×10²⁰ at/cm³, and the concentration of p-type impurities may be less than or equal to about 1×10¹⁸ at/cm³. At this time, the potential barrier region 115 may include silicon (Si), and the concentration of silicon in the entire potential barrier region 115 may be less than or equal to about 5×10²² at/cm³. Herein, the concentrations of carbon (C) or p-type impurities may be the number (at) of elements present per unit volume (cm³).

In addition, in the potential barrier region 115, the concentration of the p-type impurities may be greatest near the surface of the potential barrier region 115 but tend to decrease toward the inside from the surface of the potential barrier region 115, that is, farther away from the second device isolation layer DTI2.

On the contrary, in the potential barrier region 115, the concentration of the carbon (C) may be the greatest on the surface of the potential barrier region 115 or a specific point inside the potential barrier region 115 but tend to decrease toward the inside from vicinity of the surface of the potential barrier region 115, that is, farther away from the second device isolation layer DTI2.

For example, in the potential barrier region 115, in a region where a distance from a surface adjacent to the pair of second device isolation layers DTI2a in the third direction is less than or equal to about 50 nm, for example less than or equal to about 10 nm, a concentration of the p-type impurities may be greater than a concentration of the carbon (C). On the other hand, in a region where a distance from the surface adjacent to the pair of second device isolation layers DTI2a in the third direction is greater than about 50 nm, for example, greater than about 100 nm, a concentration of the carbon (C) is greater than a concentration of the p-type impurities.

Likewise, in the potential barrier region 115, in a region where a distance from the surface adjacent to another pair of second device isolation layers DTI2b in the second direction is less than or equal to about 50 nm, for example less than or equal to about 10 nm, a concentration of the p-type impurities may be greater than a concentration of the carbon (C). On the other hand, in a region where a distance from the surface adjacent to another pair of second device isolation layers DTI2b in the second direction is greater than about 50 nm, for example, greater than about 100 nm, a concentration of the carbon (C) is greater than a concentration of the p-type impurities.

Herein, the concentrations of carbon (C) and p-type impurities according to the distance in the second or third direction in the potential barrier region 115 can be obtained through Energy Disperse X-Ray Spectrometer (EDS) line analysis, etc.

As described above, in the image sensor 100 according to an embodiment, carbon (C) is implanted into the region doped with the p-type impurities through an ion implantation process (IIP). As the ion implantation process is used, the p-type impurities are suppressed from diffusion by adjusting the carbon (C)-doping concentration and depth.

In addition, when the potential barrier region 115 has the aforementioned concentration range and concentration profile of carbon (C) and p-type impurities, the carbon (C) may more effectively prevent the diffusion of the p-type impurities.

Referring to FIGS. 3, 4, and 5, the image sensor 100 according to an embodiments may include the substrate 110 including the first surface 111 and a second surface 112 facing each other, the first device isolation layer DTI1 separating the pixel areas PX1, PX2, PX3, and PX4 inside the substrate 110, and the second device isolation layer DTI2 disposed inside at least one of the pixel areas PX1, PX2, PX3, and PX4 to separate the first to fourth photodiodes PD1-1 to PD4-4. For example, the pixel areas PX1, PX2, PX3, and PX4 may be arranged in a direction parallel to the first surface 111.

For example, the pixel areas PX1, PX2, PX3, and PX4 may respectively include the first to fourth photodiodes PD1-1 to PD4-4. For example, the first pixel area PX1 may include the first to fourth photodiodes PD1-1, PD1-2, PD1-3, and PD1-4, the second pixel area PX2 may include the first to fourth photodiodes PD2-1, PD2-2, PD2-3, and PD2-4, the third pixel area PX3 may include the first to fourth photodiodes PD3-1, PD3-2, PD3-3, and PD3-4, and the fourth pixel area PX4 may include the first to fourth photodiodes PD4-1, PD4-2, PD4-3, and PD4-4.

Herein, the first photodiodes PD1-1, PD2-1, PD3-1, and PD4-1 and the second photodiodes PD1-2, PD2-2, PD3-2, and PD4-2 may also be separated each other in the second direction, and the third photodiodes PD1-3, PD2-3, PD3-3, and PD4-3 and the fourth photodiodes PD1-4, PD2-4, PD3-4, and PD4-4 may be separated each other in the second direction. The first photodiodes PD1-1, PD2-1, PD3-1, and PD4-1 and the third photodiodes PD1-3, PD2-3, PD3-3, and PD4-3 may be separated each other in the third direction, and the second photodiodes PD1-2, PD2-2, PD3-2, and PD4-2 and the fourth photodiodes PD1-4, PD2-4, PD3-4, and PD4-4 may also be separated each other in the third direction.

In the image sensor 100 according to an embodiment, the second device isolation layer DTI2 may include a pair of second device isolation layers DTI2a extending from the first device isolation layer DTI1 in the third direction and spaced apart from each other in the third direction and a pair of second device isolation layers DTI2b extending in the second direction from the first device isolation layer DTI1 and spaced apart from each other in the second direction. However, this is only an example embodiment, and the second device isolation layer DTI2 is not limited thereto but may be integrally extended according to embodiments.

The first device isolation layer DTI1 and the second device isolation layer DTI2 may extend in the first direction inside the substrate 110 including a semiconductor material. For example, the first device isolation layer DTI1 and the second device isolation layer DTI2 may be simultaneously or separately formed. On the other hand, the first device isolation layer DTI1 and the second device isolation layer DTI2 may be formed inside trenches formed on the first surface 111 of the substrate 110. Accordingly, the first device isolation layer DTI1 may extend toward the second surface 112 from the first surface 111 of the substrate 110. FIGS. 3 to 5 show that the first device isolation layer DTI1 and the second device isolation layer DTI2 extend toward the second surface 112 form the first surface 111 of the substrate 110. However, the first device isolation layer DTI1 and the second device isolation layer DTI2 are not limited thereto and may oppositely extent toward the first surface 111 from the second surface 112 according to embodiments.

As described above, the image sensor 100 according to an embodiment includes the potential barrier region 115 formed by implanting the p-type impurities through the plasma doping (PLAD) process before forming the first device isolation layer DTI1 and the second device isolation layer DTI2 and then, implanting the carbon (C) into the region doped with the p-type impurities through the ion implantation process (IIP).

For example, the potential barrier region 115 may be disposed between the photodiodes PD1-1 to PD4-4 of the substrate 110 and the second device isolation layer DTI2 and extend from the first surface 111 of the substrate 110 to a predetermined depth spaced apart from the second surface 112 in the first direction.

The potential barrier region 115 may be located in the isolation layer-free region DCC of the substrate 110 adjacent to the second device isolation layer DTI2. For example, the potential barrier region 115 may be located between the pair of second device isolation layers DTI2a spaced apart in the third direction and between the pair of second device isolation layers DTI2b spaced apart in the second direction. For example, the potential barrier region 115 may be located approximately in the second and third directions of the isolation layer-free region DCC in each pixel area PX1, PX2, PX3, and PX4. Accordingly, the potential barrier region 115 may be connected to each photodiode PD1-1 to PD4-4. Nevertheless, the potential barrier region 115 includes the carbon (C) and the p-type impurities and thus may not only suppress diffusion of the p-type impurities but also control movement of charges between the photodiodes PD1-1 to PD4-4.

Optionally, the substrate 110 may further include a first doped region 116a located adjacent to a sidewall of the second device isolation layer DTI2.

The first doped region 116a may include p-type impurities and carbon (C).

For example, the first doped region 116a may be formed by implanting the p-type impurities to the substrate 110 through the plasma doping (PLAD) process before forming the second device isolation layer DTI2 and then, implanting the carbon (C) into the region doped with the p-type impurities through the ion implantation process (IIP).

As an example, the p-type impurities may include boron (B), aluminum (Al), gallium (Ga), indium (In), or a combination thereof. For example, the p-type impurities may be boron (B).

In the entire first doped region 116a, the concentration of carbon (C) may be greater than the concentration of p-type impurities. For example, the concentration of carbon (C) may be about twice or more, about 5 times or more, about 10 times or more than the concentration of p-type impurities.

For example, in the entire first doped region 116a, the concentration of carbon (C) may be about 1×10¹⁸ at/cm³ to about 1×10²⁰ at/cm³, and the concentration of p-type impurities may be less than or equal to about 1×10¹⁸ at/cm³. At this time, the first doped region 116a may include silicon (Si), and the concentration of silicon in the entire first doped region 116a may be less than or equal to about 5×10²² at/cm³.

In addition, the concentration of the p-type impurities may be the greatest near the surface of the first doped region 116a and then, tend to decrease toward the inside from the surface of the first doped region 116a, that is, farther away from the first device isolation layer DTI1.

On the other hand, the concentration of the carbon (C) has a maximum value on the surface of the first doped region 116a or a specific point and then, tend to decrease toward the inside from the vicinity of the surface of the first doped region 116a, that is, farther away from the first device isolation layer DTI1.

As an example, in the first doped region 116a, in a region where a distance from the surface adjacent to the pair of second device isolation layers DTI2a in the direction perpendicular to the surface (e.g., the second direction) is less than or equal to about 50 nm, for example less than or equal to about 10 nm, a concentration of the p-type impurities may be greater than a concentration of the carbon (C). On the other hand, in a region where a distance from the surface adjacent to the pair of second device isolation layers DTI2a in the direction perpendicular to the surface (e.g., the second direction) is greater than about 50 nm, for example, greater than about 100 nm, a concentration of the carbon (C) is greater than a concentration of the p-type impurities.

Likewise, in the first doped region 116a, in a region where a distance from the surface adjacent to another pair of second device isolation layers DTI2b in the direction perpendicular to the surface (e.g., the third direction) is less than or equal to about 50 nm, for example less than or equal to about 10 nm, a concentration of the p-type impurities may be greater than a concentration of the carbon (C). On the other hand, in a region where a distance from the surface adjacent to another pair of second device isolation layers DTI2b in the direction perpendicular to the surface (e.g., the third direction) is greater than about 50 nm, for example, greater than about 100 nm, a concentration of the carbon (C) is greater than a concentration of the p-type impurities.

The image sensor 100 according to an embodiment further includes the first doped region 116a adjacent to the sidewall of the second device isolation layer DTI2 and thus may maintain charges generated from the photodiodes PD1-1 to PD4-4 by forming an electric field region as well as suppress the diffusion of the p-type impurities and also, block charges generated at one photodiode from inflowing to the other photodiodes to suppress deterioration of dark characteristics, for example, generation of white spots or dark currents.

For example, the first doped region 116a may be located on all surfaces where the substrate 110 contacts with the second device isolation layer DTI2. Accordingly, a pair of first doped regions 116a may extend along the pair of second device isolation layer DTI2a from the first device isolation layer DTI1 in the third direction, wherein the pair of first doped regions 116a may be spaced apart each other in the third direction. In addition, another pair of first doped regions 116a may extend along another pair of second device isolation layers DTI2b from the first device isolation layer DTI1 in the second direction, wherein the pair of first doped regions 116a may be spaced apart each other in the second direction. The potential barrier region 115 may be disposed between the pair of first doped regions 116a spaced apart each other, and the first doped regions 116a may be connected with the potential barrier region 115.

In addition, the first doped region 116a may extend in the first direction inside the substrate 110. For example, the first doped region 116a may extent toward the second surface 112 toward the first surface 111 of the substrate 110. However, the first doped region 116a is not limited thereto and may oppositely extend toward the first surface 111 from the second surface 112 according to embodiments.

Optionally, the substrate 110 may further include a second doped region 116b adjacent to the sidewall of the first device isolation layer DTI1.

The second doped region 116b may include p-type impurities and carbon (C).

For example, the second doped region 116b may be formed by implanting the p-type impurities into the substrate 110 through the plasma doping (PLAD) process before forming the first device isolation layer DTI1 and then, implanting the carbon (C) into a region doped with the p-type impurities through the ion implantation process (IIP).

As an example, the p-type impurities may include boron (B), aluminum (Al), gallium (Ga), indium (In), or a combination thereof. For example, the p-type impurities may be boron (B).

In the entire bulk of the second doped region 116b, the concentration of carbon (C) may be greater than the concentration of p-type impurities. For example, the concentration of carbon (C) may be about twice or more, about 5 times or more, about 10 times or more than the concentration of p-type impurities.

For example, in the entire second doped region 116b, the concentration of carbon (C) may be about 1×10¹⁸ at/cm³ to about 1×10²⁰ at/cm³, and the concentration of p-type impurities may be less than or equal to about 1×10¹⁸ at/cm³. At this time, the second doped region 116b may include silicon (Si), and the concentration of silicon in the entire second doped region 116b may be less than or equal to about 5×10²² at/cm³.

In addition, the concentration of the p-type impurities may be the greatest adjacent to the surface of the second doped region 116b and tend to decrease toward the inside from the surface of the second doped region 116b, that is, farther away from the second device isolation layer DTI2.

On the contrary, the concentration of the carbon (C) may have a maximum value on the surface of the second doped region 116b or at a specific point inside the second doped region 116b and then, tend to decrease toward the inside from the vicinity of the surface of the second doped region 116b, that is, farther from the second device isolation layer DTI2.

For example, in the second doped region 116b, in a region where a distance from the surface adjacent to the first device isolation layer DTI1 in a direction perpendicular to the surface (e.g., the second or third direction) is less than or equal to about 50 nm, for example less than or equal to about 10 nm, a concentration of the p-type impurities may be greater than a concentration of the carbon (C). On the other hand, in a region where the distance from the surface adjacent to the first device isolation layer DTI1 in the direction perpendicular to the surface (e.g., the second or third direction) is greater than about 50 nm, for example, greater than about 100 nm, a concentration of the carbon (C) is greater than a concentration of the p-type impurities.

The image sensor 100 according to an embodiment further includes a second doped region 116b adjacent to a side wall of the first device isolation layer DTI1 and thus may suppress diffusion of the p-type impurities and also, maintain charges generated in the photodiodes PD1-1 to PD4-4 by forming an electric field region and block charges generated in one photodiode from inflowing into the other photodiodes to suppress deterioration of dark characteristics, for example, generation of white spots or dark currents.

For example, the second doped region 116b may be located on all the surfaces where the substrate 110 contacts with the first device isolation layer DTI1. Accordingly, the second doped region 116b may extend along the first device isolation layer DTI1 in the second and third directions between the pixel areas PX1, PX2, PX3, and PX4. The second doped region 116b may be connected to the first doped region 116a in a region where the first device isolation layer DTI1 contacts with the second device isolation layer DTI2 but not connected with the potential barrier region 115 and spaced apart each other from the potential barrier region 115.

The second doped region 116b may extend in the first direction inside the substrate 110. For example, the second doped region 116b may extend from the first surface 111 of the substrate 110 toward the second surface 112. However, the second doped region 116b is not limited thereto and oppositely may extent toward the first surface 111 from the second surface 112 according to embodiments.

Optionally, the substrate 110 may further include a third doped region 117 on the first surface 111 of the substrate 110.

The third doped region 117 may include p-type impurities and carbon (C).

For example, the third doped region 117 may be formed by implanting the p-type impurities into the first surface 111 of the substrate 110 through the plasma doping (PLAD) process and then, implanting the carbon (C) into a region doped with the p-type impurities through the ion implantation process (IIP).

As an example, the p-type impurities may include boron (B), aluminum (Al), gallium (Ga), indium (In), or a combination thereof. For example, the p-type impurities may be boron (B).

In the entire bulk of the third doped region 117, the concentration of carbon (C) may be greater than the concentration of p-type impurities. For example, the concentration of carbon (C) is about twice or more, about 5 times or more, about 10 times or more than the concentration of p-type impurities.

For example, in the entire third doped region 117, the concentration of carbon (C) may be about 1×10¹⁸ at/cm³ to about 1×10²⁰ at/cm³, and the concentration of p-type impurities may be less than or equal to about 1×10¹⁸ at/cm³. At this time, the third doped region 117 may include silicon (Si), and the concentration of silicon in the entire third doped region 117 may be less than or equal to about 5×10²² at/cm³.

In addition, the concentration of the p-type impurities may be the greatest near the surface of the third doped region 117 and tend to decrease toward the inside from the surface of the third doped region 117, that is, nearer to first to fourth photodiodes PD1-1 to PD4-4.

On the contrary, the concentration of the carbon (C) has a maximum value on the surface of the third doped region 117 or at a specific point inside the third doped region 117 and then, tend to decrease toward the inside from the vicinity of the surface of the third doped region 117, that is, nearer to the first to fourth photodiodes PD1-1 to PD4-4.

For example, in the third doped region 117, in a region where a distance from the first surface 111 in the first direction is less than or equal to about 50 nm, for example less than or equal to about 10 nm, a concentration of the p-type impurities may be greater than a concentration of the carbon (C). On the other hand, in a region where the distance from the first surface 111 in the first direction is greater than 50 nm, for example, greater than 100 nm, a concentration of the carbon (C) is greater than a concentration of the p-type impurities. Herein, the concentrations of carbon (C) and p-type impurities according to the distance in the second or third direction in the third doped region 117 can be obtained through EDS (Energy Disperse X-Ray Spectrometer) line analysis.

The image sensor 100 according to an embodiment further includes the third doped region 117 on the first surface 111 of the substrate 110 and thus may suppress diffusion of the p-type impurities and maintain charges generated in the photodiodes PD1-1 to PD4-4 by forming an electric field region and also, block charges generated in one photodiode from inflowing into the other photodiodes to suppress deterioration of dark characteristics, for example, generation of white spots or dark currents.

For example, the third doped region 117 may be located on at least a portion or the entire surface of the first surface 111 of the substrate 110. Accordingly, as will be described later, the image sensor 100 may further include a transfer transistor disposed on the first surface 111 of the substrate 110 in each pixel area PX1, PX2, PX3, and PX4, wherein the third doped region 117 may be located between the transfer transistor and the first surface 111 of the substrate 110.

In addition, the image sensor 100 may further include a floating diffusion region 150 disposed adjacent to the transfer transistor inside the first surface 111 of the substrate 110, wherein the third doped region 117 may be disposed between the floating diffusion region 150 and the first surface 111 of the substrate 110.

On the other hand, referring to FIGS. 3 to 5, the first and second device isolation layers DTI1 and DTI2, the photodiodes PD1-1 to PD4-4, and the potential barrier region 115 may exhibit various cross-sections according to a cutting position and a cutting direction.

For example, the first and third pixel areas PX1 and PX3, the first and third photodiodes PD1-1, PD1-3, PD3-1, and PD3-3, the first and second device isolation layers DTI1 and DTI2, and the first, second, and third doped regions 116a, 116b, and 117 may be seen in FIG. 3. In FIG. 4, the first and third pixel areas PX1 and PX3, the first and second device isolation layers DTI1 and DTI2, and the potential barrier region 115 may be seen. In addition, in FIG. 5, the first and fourth pixel areas PX1 and PX4, the first and fourth photodiodes PD1-1, PD1-4, PD4-1, and PD4-4, the first device isolation layer DTI1, the potential barrier region 115, the second and third doped regions 116b and 117 may be seen.

In addition, the image sensor 100 according to an embodiment may further include various components required for driving the image sensor 100. For example, the pixel areas PX1, PX2, PX3, and PX4 respectively may include a color filter 120, a light transmittance layer 130, and a micro lens 140 on the second surface 112 of the substrate 110. For example, each pixel areas PX1. PX2, PX3, and PX4 may include one micro lens 140 disposed on the first to fourth photodiodes PD1-1 to PD4-4. Accordingly, light after passing one micro lens 140 may enter the first to fourth photodiodes PD1-1 to PD4-4.

On the other hand, a pixel circuit may be disposed under the first to fourth photodiodes PD1-1 to PD4-4. For example, the pixel circuit may include a plurality of devices 160, wire patterns 170 connected with the plurality of devices 160, an insulation layer 180 covering the plurality of devices 160 and the wire patterns 170, and the like and may be disposed on the first surface 111 of the substrate 110.

In addition, the substrate 110 may further include the floating diffusion region 150. For example, each of the pixel areas PX1, PX2, PX3, and PX4 may include the floating diffusion region 150 disposed under at least one of the first to fourth photodiodes PD1-1 to PD4-4. For example, each floating diffusion region 150 may be electrically connected to at least one of the wire patterns 170, wherein a position, an area, and etc. of the floating diffusion regions 150 may be variously modified according to embodiments.

In the image sensor 100 according to an embodiment, the plurality of devices 160 adjacent to the floating diffusion regions 150 may be a transfer transistor. For example, a transfer transistor gate may have a vertical structure that at least a portion of its area is buried in the substrate 110.

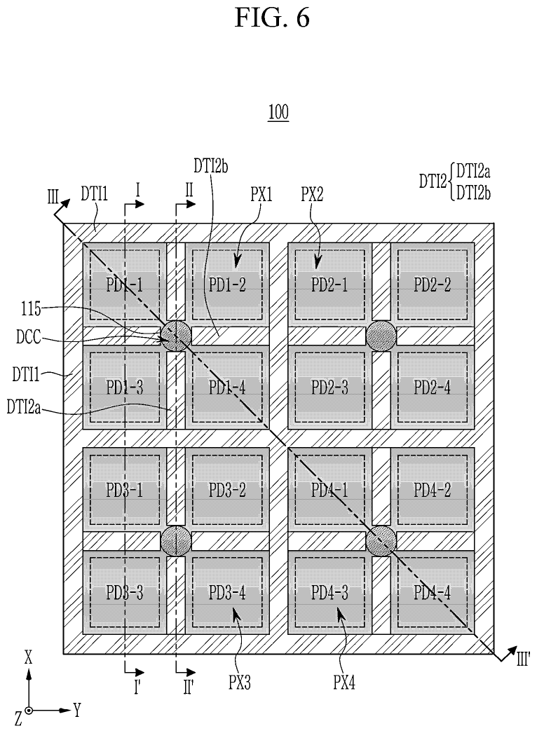

Hereinafter, the image sensor 100 according to another embodiment will be described with reference to FIGS. 6 to 9.

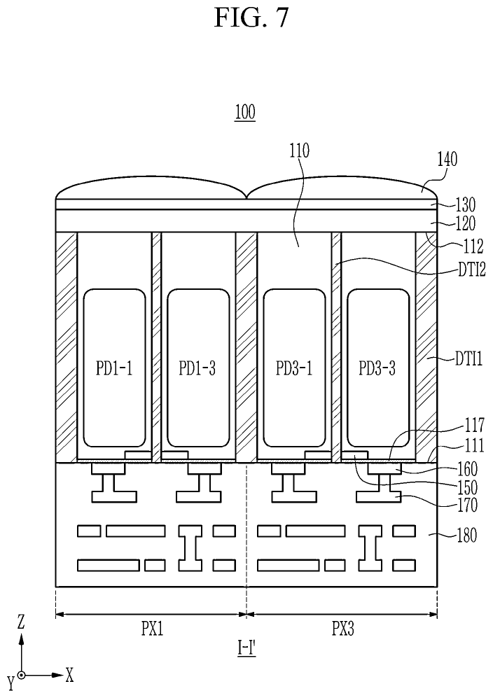

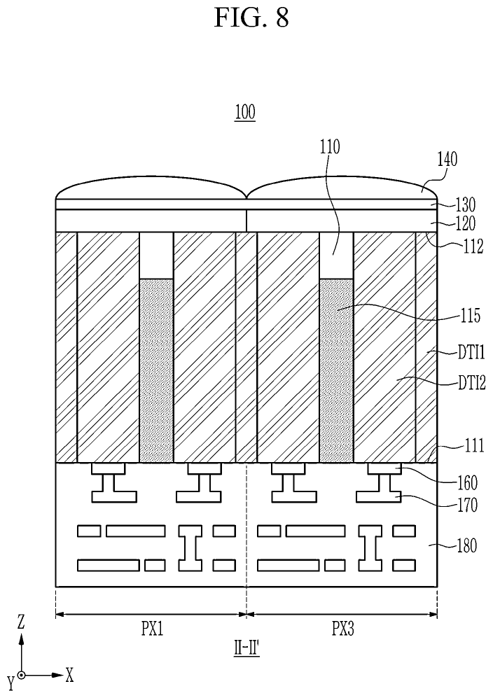

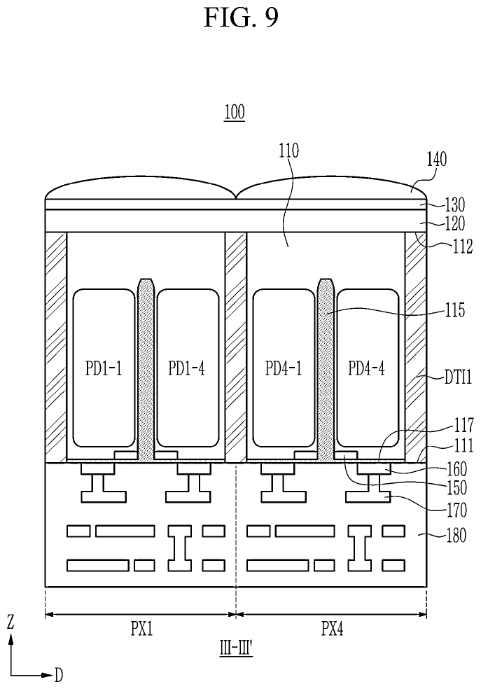

FIG. 6 is a top view of an image sensor according to another embodiment, FIG. 7 is a cross-sectional view taken along line I-I′ of FIG. 6; FIG. 8 is a cross-sectional view taken along line II-II′ of FIG. 6, and FIG. 9 is a cross-sectional view taken along line III-III′ of FIG. 6.

Since the embodiment shown in FIGS. 6 to 9 is substantially the same as the embodiment shown in FIGS. 2 and 5, the descriptions thereof will be omitted and the differences will be mainly explained.

In FIGS. 2 and 5, the substrate 110 is illustrated to all include the potential barrier region 115 between the photodiodes PD1-1 to PD4-4 and the second device isolation layer DTI2, the first doped region 116a disposed adjacent to a sidewall of the second device isolation layer DTI2, the second doped region 116b disposed adjacent to a sidewall of the first device isolation layer DTI1, and the third doped region 117 on the first surface 111 of the substrate 110.

Referring to FIGS. 6 to 9, the substrate 110 is illustrated to only include the potential barrier region 115 disposed between the photodiodes PD1-1 to PD4-4 and the second device isolation layer DTI2 and the third doped region 117 disposed on the first surface 111 of the substrate 110. In other words, the image sensor 100 according to another example embodiment may not include the first doped region 116a disposed adjacent to a side wall of the second device isolation layer DTI2 and the second doped region 116b disposed adjacent to a side wall of the first device isolation layer DTI1.

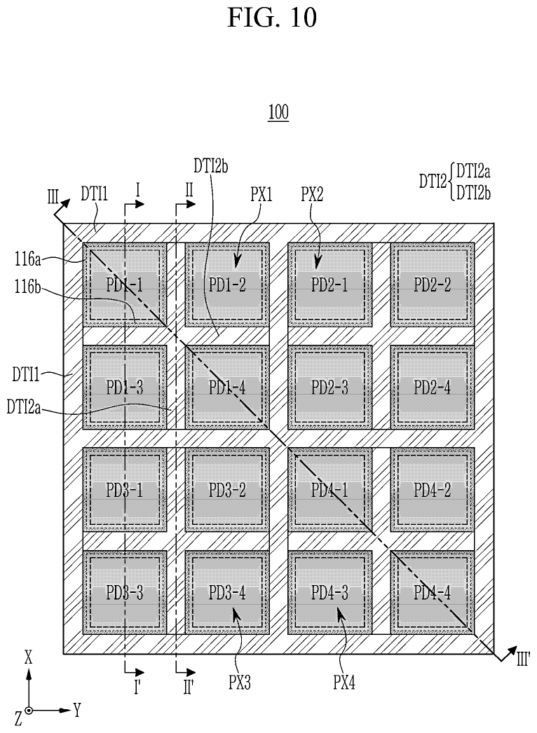

Hereinafter, the image sensor 100 according to another embodiment will be described with reference to FIGS. 10 to 13.

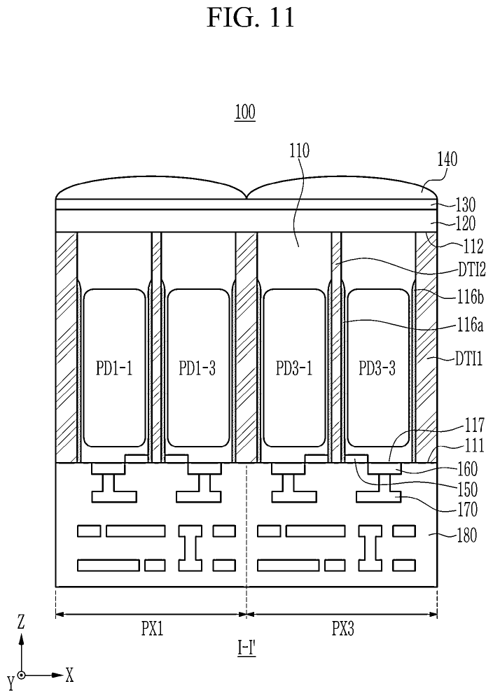

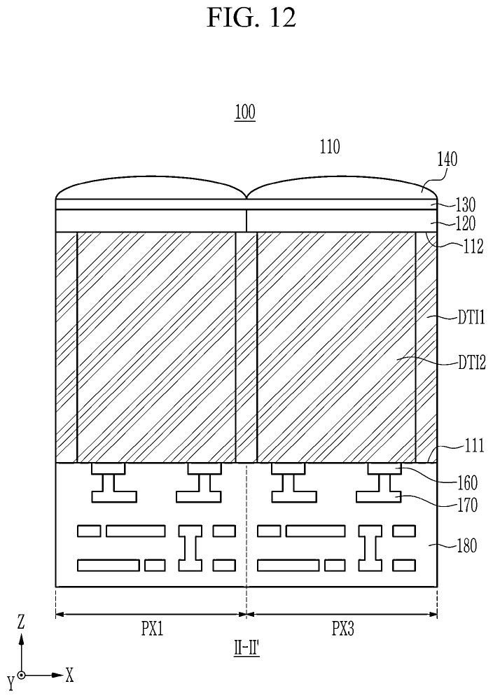

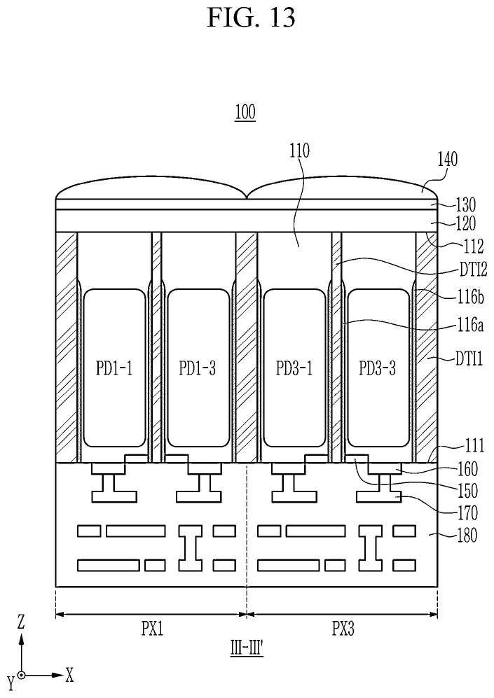

FIG. 10 is a top view of an image sensor according to another embodiment, FIG. 11 is a cross-sectional view taken along line I-I′ of FIG. 10, FIG. 12 is a cross-sectional view taken along line II-II′ of FIG. 10, and FIG. 13 is a cross-sectional view taken along line III-III′ of FIG. 10.

Since the embodiment shown in FIGS. 10 to 13 has many of the same parts as the embodiment shown in FIGS. 2 and 5, descriptions thereof will be omitted and the differences will be mainly explained.

In FIGS. 2 and 5, the substrate 110 is illustrated to all include the potential barrier region 115 disposed between the photodiodes PD1-1 to PD4-4 and the second device isolation layer DTI2, the first doped region 116a disposed adjacent to a sidewall of the second device isolation layer DTI2, the second doped region 116b disposed adjacent to a sidewall of the first device isolation layer DTI1, and the third doped region 117 on the first surface 111 of the substrate 110.

In FIGS. 10 to 13, the substrate 110 is illustrated to only include the first doped region 116a disposed adjacent to a sidewall of the second device isolation layer DTI2 and the second doped region 116b disposed adjacent to a sidewall of the first device isolation layer DTI1. In other words, the image sensor 100 according to another example embodiment may not include the potential barrier region 115 disposed between the photodiodes PD1-1 to PD4-4 and the second device isolation layer DTI2 and the third doped region 117 disposed on the first surface 111 of the substrate 110.

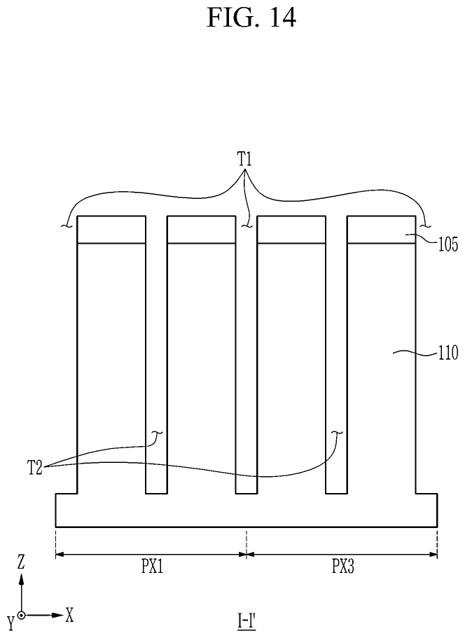

Hereinafter, a method of manufacturing the image sensor 100 according to an embodiment will be described with reference to FIGS. 14 to 24.

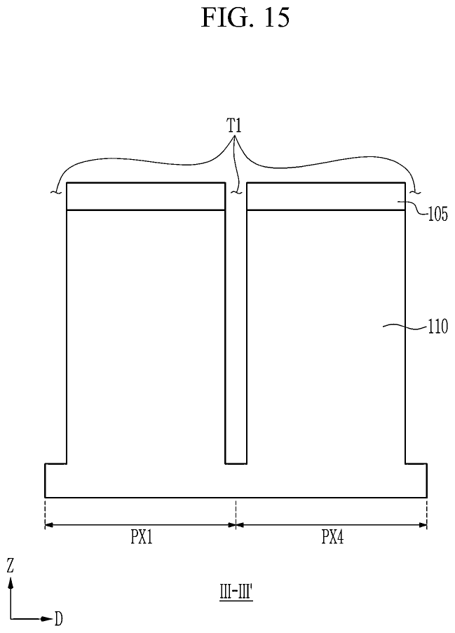

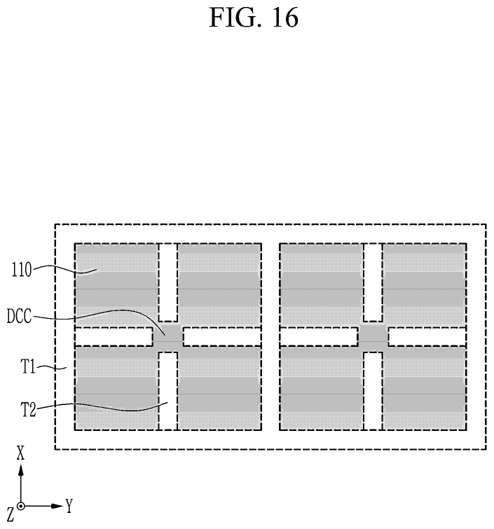

FIGS. 14 to 24 are a cross-sectional view and a top view at a certain step of manufacturing the image sensor 100 according to an embodiment. For example, the cross-section shown in FIG. 14 may be a cross-sectional view at a certain step of manufacturing the image sensor 100 shown in FIG. 3, the cross-section shown in FIG. 15 may be a cross-sectional view at a certain step of manufacturing the image sensor 100 shown in FIG. 5, and the top view of FIG. 16 may be a top view at a certain step of manufacturing the image sensor 100 shown in FIG. 2.

Referring to FIGS. 14 and 16, the method of manufacturing the image sensor 100 according to an embodiment may include a step of forming a first trench T1 extending in the first direction to separate the pixel areas PX1, PX2, PX3, and PX4 in the substrate 110.

In addition, the method of manufacturing the image sensor 100 according to an embodiment may include a step of forming a pair of second trenches T2, which extend from the first trench T1 in the third direction between regions for forming the first photodiodes PD1-1, PD2-1, PD3-1, and PD4-1 and the second photodiodes PD1-2, PD2-2, PD3-2, and PD4-2, extending between regions for forming the third photodiodes PD1-3, PD2-3, PD3-3, and PD4-3 and the fourth photodiodes PD1-4, PD2-4, PD3-4, and PD4-4 and are spaced apart each other in the third direction.

In addition, the method of manufacturing the image sensor 100 according to an embodiment may further include a step of forming another pair of second trenches T2, which extend from the first trench T1 in the second direction between regions for forming the first photodiodes PD1-1, PD2-1, PD3-1, and PD4-1 and the third photodiodes PD1-3, PD2-3, PD3-3, and PD4-3, extend between regions for forming the second photodiodes PD1-2, PD2-2, PD3-2, and PD4-2 and the fourth photodiodes PD1-4, PD2-4, PD3-4, and PD4-4 and are spaced apart each other in the second direction.

For example, the steps of forming the first trench T1 and the second trenches T2 may proceed sequentially or simultaneously. However, this is only an embodiment, but the present disclosure may not be limited thereto.

In the method of manufacturing the image sensor 100 according to an embodiment, a first mask layer 105 may be formed on one upper surface of the substrate 110 to form the first trench T1 and the second trenches T2. For example, the first mask layer 105 may be a layer protecting the substrate 110 from being etching during the etching process for forming the first trench T1 and the second trenches T2. After forming the first mask layer 105, the first trench T1 and the second trenches T2 may be formed in the subsequent etching process.

The first trench T1 and the second trenches T2 shown in FIGS. 14, 15, and 16 are illustrated to have the same thickness and the same depth but are not limited thereto and may have various shapes of changed according to embodiments.

Referring to FIGS. 17 to 19, the method of manufacturing the method according to an embodiment may include a step of forming the potential barrier region 115 by doping the p-type impurities in the isolation layer-free region DCC of the substrate 110 located between the pair of second trenches T2 and exposed through the second trenched T2 and then, implanting the carbon (C) thereinto.

For example, the doping of the p-type impurities may be performed through the plasma doping (PLAD) process.

When the plasma doping process is used to dope boron (B) as the p-type impurities, source materials such as boron (B), boron difluoride (BF₂), boron trifluoride (BF₃), or the like may be used as impurity gas. These source materials may be supplied in a gaseous state into a process chamber. After plasma-ionizing the source materials, when a high voltage bias is applied to a static electricity on which the substrate 110 is loaded, cations of the p-type impurities in the plasma may be accelerated and implanted into the substrate 110. The plasma doping may realize relatively uniform doping at very deep locations and improve a doping process speed.

For example, the carbon (C) implantation may be performed through the ion implantation process (IIP). The ion implantation process may implant the carbon (C) into the substrate 110 by using an incident beam 107.

For example, the isolation layer-free region DCC of the substrate 110 which is doped with the p-type impurities and the carbon (C) may be defined as the potential barrier region 115. However, the present disclosure may not be limited to which is shown in FIGS. 17 to 19. For example, a length of the potential barrier region 115 in the first direction may vary according to embodiments.

In addition, referring to FIGS. 17 to 19, impurities may also be doped onto at least a portion of an inner sidewall of the first trench T1 and an inner sidewall of the second trenches T2, which may respectively form the first doped region 116a and the second doped region 116b.

Optionally, after implanting the carbon (C) through the ion implantation process, the p-type impurities may be further implanted through the ion implantation process. In addition, after further implanting the p-type impurities through the ion implantation process, the carbon (C) may be further implanted through the implant ion implantation process. Accordingly, the potential barrier region 115 is formed to have the aforementioned concentration ranges and concentration profiles of the carbon (C) and the p-type impurities, so that the carbon (C) may effectively prevent diffusion of the p-type impurities.

In the method of manufacturing the image sensor 100 according to an embodiment, in order to form the potential barrier region 115, a second mask layer 106 may be formed on the top surface of the first mask layer 105. For example, the second mask layer 106 may include a photosensitive polymer material. For example, the second mask layer 106 may be a layer to prevent channeling into the substrate 110 during the ion implantation process. However, this is only an embodiment, but the ion implantation process is not limited thereto and may proceed with the first mask layer 105 alone without forming the second mask layer 106.

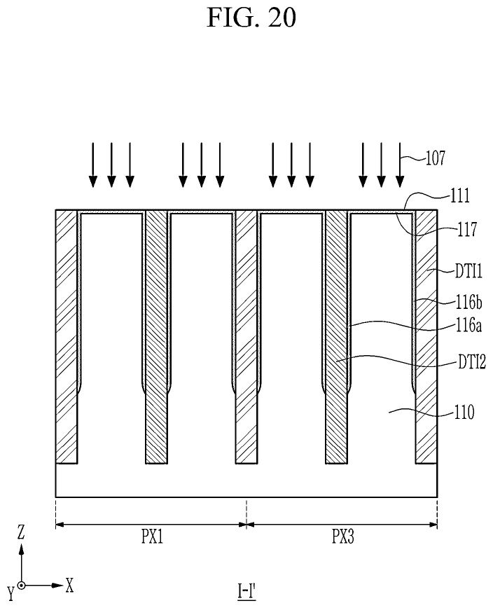

Referring to FIGS. 20 to 22, the method of manufacturing the image sensor 100 according to an embodiment may optionally further include a step of forming the third doped region 117 by doping the p-type impurities on the first surface 111 of the substrate 110 through the plasma doping process after removing the first mask layer 105 and the second mask layer 106 and then, implanting the carbon (C) through the ion implantation process.

However, the step of forming the potential barrier region 115 is only an example embodiment and embodiments are not limited thereto, and the potential barrier region 115 may be formed without the first and second mask layers 105 and 106 or simultaneously formed with the third doped region 117 by forming the potential barrier region 115 after removing the first and second mask layers 105 and 106.

Subsequently, the method of manufacturing the image sensor 100 according to an embodiment may include a step of forming the first device isolation layer DTI1 inside the first trench T1 and the second device isolation layer DTI2 inside the second trench T2.

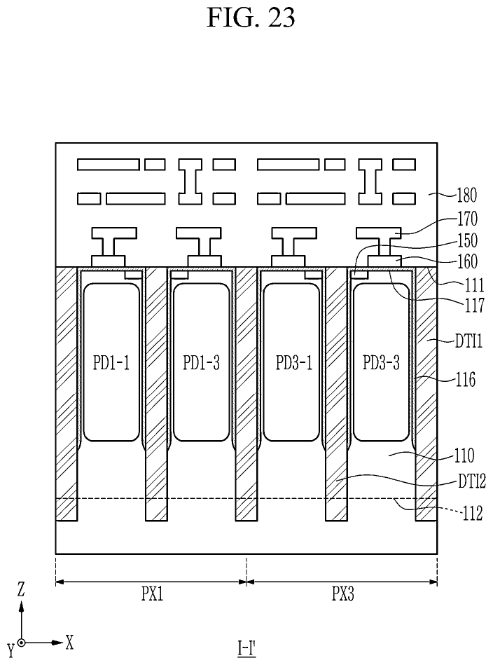

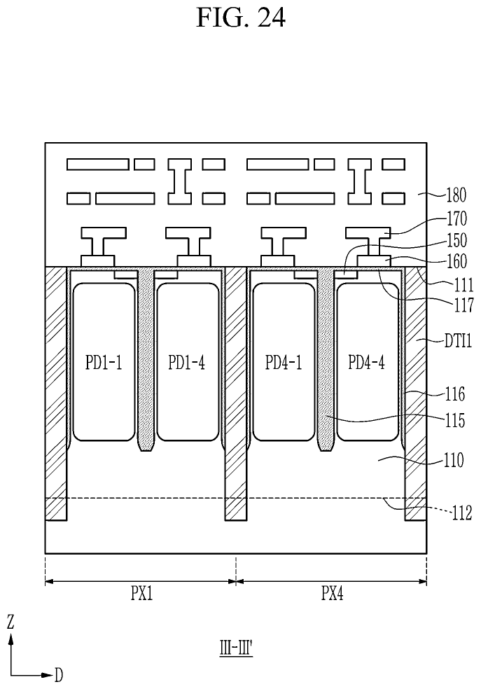

Referring to FIGS. 23 to 24, the method of manufacturing the image sensor 100 according to an embodiment may include a step of disposing the pixel circuit on the first surface 111 of the substrate 110. As described above, the pixel circuit may include the plurality of devices 160, the wire patterns 170 connected with the plurality of devices 160, the insulation layer 180 covering the plurality of devices 160 and the wire patterns 170, and the like.

On the other hand, from the other side of the pixel circuit, some regions of the substrate 110 may be removed by a polishing process. For example, the removed region may include portions of the first device isolation layer DTI1 and the second device isolation layer DTI2. For example, one surface of the substrate 110 remaining after being removed by the polishing process may be defined as the second surface 112.

On the other hand, the method of manufacturing the image sensor 100 according to an embodiment may further include forming the color filter 120, the light transmittance layer 130, and the micro lens 140 sequentially on the defined second surface 112. Through this, the image sensor 100 shown in FIGS. 2 to 5 may be manufactured.

While certain example embodiments of the disclosure have been shown and described, it is to be understood that the disclosure is not limited to the disclosed embodiments, but, on the contrary, is intended to cover various modifications and equivalent arrangements included within the spirit and scope of the appended claims.

What is claimed is:

1. An image sensor comprising:
a substrate having a first surface and a second surface opposite to the first surface in a first direction, the substrate comprising pixel areas arranged along a second direction parallel to the first surface;
photodiodes in the substrate in each of the pixel areas and separated from each other in the second direction;
a first device isolation layer between the pixel areas; and
a pair of second device isolation layers extending between the photodiodes from the first device isolation layer along a third direction and being spaced apart from each other in the third direction,
wherein the third direction is parallel to the first surface and different from the second direction, and
wherein the substrate further comprises a potential barrier region between the photodiodes and between the pair of second device isolation layers, and the potential barrier region comprises p-type impurities and carbon.

2. The image sensor of claim 1, wherein the p-type impurities comprise boron, aluminum, gallium, indium, or a combination thereof.

3. The image sensor of claim 1, wherein a concentration of the carbon in the potential barrier region is greater than a concentration of the p-type impurities in the potential barrier region.

4. The image sensor of claim 1, wherein a concentration of the carbon in the potential barrier region is about 1×10¹⁸ at/cm³ to about 1×10²⁰ at/cm^{3,} and
wherein a concentration of the p-type impurities in the potential barrier region is less than or equal to about 1×10¹⁸ at/cm³.

5. The image sensor of claim 1, wherein the potential barrier region further comprises silicon, and
wherein a concentration of the silicon in the potential barrier region is less than or equal to about 5×10²² at/cm³.

6. The image sensor of claim 1, wherein, in a first region of the potential barrier region where a distance from a surface adjacent to the second device isolation layers in the third direction is less than or equal to about 50 nm, a concentration of the p-type impurities is greater than a concentration of the carbon, and
wherein, in a second region of the potential barrier region where a distance from the surface adjacent to the second device isolation layers in the third direction is greater than about 50 nm, a concentration of the carbon is greater than a concentration of the p-type impurities.

7. The image sensor of claim 1, wherein the potential barrier region extends along the first direction from the first surface of the substrate to a depth spaced from the second surface of the substrate.

8. The image sensor of claim 1, further comprising:
photodiodes separated in the third direction in each of the pixel areas; and
another pair of second device isolation layers extending from the first device isolation layer between the photodiodes along the second direction and spaced apart from each other in the second direction,
wherein the potential barrier region is between the photodiodes and the second device isolation layers.

9. The image sensor of claim 1, wherein the potential barrier region is in a central region of each of the pixel areas.

10. The image sensor of claim 1, wherein the photodiodes are connected to the potential barrier region.

11. The image sensor of claim 1, wherein the substrate further comprises a first doped region adjacent to a sidewall of the second device isolation layers, and the first doped region comprises p-type impurities and carbon.

12. The image sensor of claim 1, wherein the substrate further comprises a second doped region adjacent to a sidewall of the first device isolation layer, and the second doped region comprises p-type impurities and carbon.

13. The image sensor of claim 1, wherein the substrate further comprises a third doped region on the first surface, and the third doped region comprises p-type impurities and carbon.

14. The image sensor of claim 13, further comprising:
a transfer transistor on the first surface of the substrate in each of the pixel areas,
wherein the third doped region is between the transfer transistor and the first surface of the substrate.

15. The image sensor of claim 13, wherein the substrate further comprises a floating diffusion region adjacent to the transfer transistor and in the first surface of the substrate, and
wherein the third doped region is between the floating diffusion region and the first surface of the substrate.

16. An image sensor comprising:
a substrate having a first surface and a second surface opposite to the first surface in a first direction, the substrate comprising pixel areas arranged along a second direction parallel to the first surface;
photodiodes in the substrate in each of the pixel areas and separated from each other in the second direction;
a first device isolation layer between the pixel areas; and
a pair of second device isolation layers extending between the photodiodes from the first device isolation layer along a third direction and being spaced apart from each other in the third direction, wherein the third direction is parallel to the first surface and different from the second direction;
wherein the substrate further comprises a first doped region adjacent to a sidewall of the second device isolation layers, and the first doped region comprises p-type impurities and carbon,
wherein, in a first region of the first doped region where a distance from a surface adjacent to the second device isolation layers in a vertical direction is less than or equal to about 50 nm, a concentration of the p-type impurities is greater than a concentration of the carbon, and
wherein, in a second region of the first doped region where a distance from surface adjacent to the second device isolation layers in the vertical direction is greater than about 50 nm, a concentration of the carbon is greater than a concentration of the p-type impurities.

17. The image sensor of claim 16, wherein the substrate further comprises a second doped region adjacent to a sidewall of the first device isolation layer, the second doped region comprising p-type impurities and carbon,
wherein, in a first region of the second doped region where a distance from a surface adjacent to the first device isolation layer in the vertical direction is less than or equal to about 50 nm, a concentration of the p-type impurities is greater than a concentration of the carbon, and
wherein, in a second region of the second doped region where a distance from surface adjacent to the second device isolation layers in the vertical direction is greater than about 50 nm, a concentration of the carbon is greater than a concentration of the p-type impurities.

18. The image sensor of claim 16, wherein the substrate further comprises a second doped region adjacent to a sidewall of the first device isolation layer, the second doped region comprising p-type impurities and carbon, and
wherein, in each of the first doped region and the second doped region, the concentration of the carbon is greater than the concentration of the p-type impurities.

19. The image sensor of claim 16, wherein the substrate further comprises a second doped region adjacent to a sidewall of the first device isolation layer, the second doped region comprising p-type impurities and carbon, and
wherein, in each of the first doped region and the second doped region, the concentration of the carbon (C) is about 1×10¹⁸ at/cm³ to about 1×10²⁰ at/cm³, and the concentration of the p-type impurities is less than or equal to about 1×10¹⁸ at/cm³.

20. An image sensor comprising:
a substrate having a first surface and a second surface opposite to the first surface in a first direction, the substrate comprising pixel areas arranged along a second direction parallel to the first surface;
photodiodes in the substrate in each of the pixel areas and separated from each other in the second direction and a third direction parallel to the first surface and different from the second direction;
a first device isolation layer between the pixel areas;
a pair of second device isolation layers extending between the photodiodes from the first device isolation layer along the third direction and spaced apart from each other in the third direction; and
another pair of second device isolation layers extending from the first device isolation layer between the photodiodes along the second direction and spaced apart from each other in the second direction,
wherein the substrate further comprises:
a potential barrier region between the photodiodes and the second device isolation layers;
a first doped region adjacent to a sidewall of the second device isolation layers;
a second doped region adjacent to a sidewall of the first device isolation layer; and
a third doped region on the first surface, and
wherein each of the potential barrier region, the first doped region, the second doped region, and the third doped region comprises p-type impurities and carbon.
